(19) United States
(12) Patent Application Publication
(10) Pub. No.: US 2026/0313966 A1
(43) Pub. Date: Oct. 8, 2026

(54) Dual Gate Thin Film Transistor and Display Apparatus with the Same

(71) Applicant: LG Display Co., Ltd., Seoul (KR)

(72) Inventors: JungHyun Lee, Paju-si (KR); Minho Lee, Paju-si (KR); ChanYong Jeong, Paju-si (KR)

(21) Appl. No.: 19/378,286

(22) Filed: Nov. 3, 2025

(30) Foreign Application Priority Data
Dec. 26, 2024 (KR) 10-2024-0196774

(51) Int. Cl. H10D 30/67; H10D 86/60

(52) U.S. Cl. CPC H10D 30/6734; H10D 86/60

(57) ABSTRACT

The present disclosure provides the dual gate thin film transistor including a first thin film transistor and a second thin film transistor connected in series, with a first gate electrode and a second gate electrode being connected to each other. The first channel part of the first thin film transistor and the first gate electrode overlap each other with a first insulating layer interposed therebetween, and the second channel part of the second thin film transistor and the second gate electrode overlap each other with a plurality of insulating layers including the first insulating layer and a second insulating layer interposed therebetween.

### CROSS-REFERENCE TO RELATED APPLICATION

This application claims the benefit of priority of the Republic of Korea Patent Application No. 10-2024-0196774 filed on Dec. 26, 2024, which is hereby incorporated by reference in its entirety.

### BACKGROUND

### Field of Technology

The present disclosure relates to a dual gate thin film transistor and a display device including the same.

### Discussion of the Related Art

The display device includes a Thin Film Transistor (TFT) that is used as a switching element or driving element of the pixel circuit and driving circuit in the display panel.

Thin film transistors may deteriorate and their reliability may be reduced due to High Drain Current Stress (HDCS) caused by the application of high potential voltage as the operating time increases.

If thin film transistors deteriorate and become less reliable, the reliability or picture quality of the display device may deteriorate.

### SUMMARY

The present disclosure provides a dual gate thin film transistor capable of reducing deterioration of the thin film transistor and a display device including the same.

The problems to be solved in this disclosure are not limited to the problems mentioned above, and other problems not mentioned may be clearly understood by a person having ordinary skill in the technical field to which the technical idea of this disclosure belongs from the description below.

According to one embodiment of the present disclosure, a dual gate thin film transistor may comprise a first thin film transistor including a first gate electrode, a first drain electrode, a first source electrode, a first channel part between the first drain electrode and the first source electrode, and a second thin film transistor including a second gate electrode connected to the first gate electrode, a second drain electrode connected to the first source electrode, a second source electrode, a second channel part between the second drain electrode and the second source electrode, wherein the first channel part and the first gate electrode overlap with each other with a first insulating layer interposed therebetween, and the second channel part and the second gate electrode overlap with each other with a plurality of insulating layers including the first insulating layer and a second insulating layer interposed therebetween.

According to one embodiment of the present disclosure, a dual gate thin film transistor may comprise a first thin film transistor including a first gate electrode, a first drain electrode, a first source electrode, and a first channel part between the first drain electrode and the first source electrode, and a second thin film transistor including a second gate electrode connected to the first gate electrode, a second drain electrode connected to the first source electrode, a second source electrode, and a second channel part between the second drain electrode and the second source electrode, wherein the second thin film transistor further comprises a second light shielding electrode overlapping the second channel part, and the first gate electrode and second gate electrode are disposed in the same layer and formed integrally.

According to one embodiment of the present disclosure, a display may comprise a display panel and a gate driving circuit for driving gate lines of the display panel, wherein the gate driving circuit comprises a stage circuit that outputs a gate signal to each of the gate lines, the stage circuit includes an output part configured to output a gate signal through a gate output line in response to control of a first control node and a second control node, a first charging part for charging the first control node, a first discharging part for discharging the first control node, a second charging part for charging the second control node, and a second discharging part for discharging the second control node, wherein the second charging part may include the dual gate thin film transistor connected between a high potential power supply line supplied with a high potential power supply voltage and the second control node, first and second gate electrodes and a first drain electrode of the dual gate thin film transistor are connected to the high potential power supply line, and a second source electrode may be connected to the second control node.

A display device according to an embodiment comprises a plurality of subpixels disposed in a display area of the display panel, wherein each of the plurality of subpixels comprises a light emitting element and a pixel circuit configured to independently drive the light emitting element, and the pixel circuit includes a driving transistor configured to drive the light emitting element, and a sampling thin film transistor configured to connect a gate electrode and a drain electrode of the driving transistor, and the sampling thin film transistor may include the dual-gate thin film transistor.

According to one embodiment of the present disclosure, a dual gate thin film transistor may comprise a first thin film transistor including a first gate electrode, a first drain electrode, a first source electrode, and a first channel part between the first drain electrode and the first source electrode, and a second thin film transistor including a second gate electrode connected to the first gate electrode, a second drain electrode connected to the first source electrode, a second source electrode, and a second channel part between the second drain electrode and the second source electrode. The first channel part and the second channel part may be formed on the same layer. A first distance between the first channel part and the first gate electrode may be less than a second distance between the second channel part and the second gate electrode.

Specific details according to various embodiments of the present disclosure other than the means for solving the problems mentioned above are included in the description and drawings below.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1A and FIG. 1B are equivalent circuit diagrams of a thin film transistor according to one embodiment of the present disclosure.

FIG. 2 is a plan view illustrating a thin film transistor structure according to one embodiment of the present disclosure.

FIG. 3 is a cross-sectional view illustrating a thin film transistor structure along lines A1-A1′ and A2-A2′ shown in FIG. 2.

FIG. 4 is a plan view illustrating a thin film transistor structure according to one embodiment of the present disclosure.

FIG. 5 is a cross-sectional view illustrating a thin film transistor structure along line B-B′ shown in FIG. 4.

FIG. 6 is a plan view illustrating a thin film transistor structure according to one embodiment of the present disclosure.

FIG. 7 is a cross-sectional view illustrating a thin film transistor structure along lines C1-C1′ and C2-C2′ shown in FIG. 6.

FIG. 8 is a plan view illustrating a thin film transistor structure according to one embodiment of the present disclosure.

FIG. 9 is a cross-sectional view illustrating a thin film transistor structure along the line D-D′ shown in FIG. 8.

FIG. 10 is a plan view illustrating a thin film transistor structure according to one embodiment of the present disclosure.

FIG. 11 is a cross-sectional view illustrating a thin film transistor structure along the line E-E′ shown in FIG. 10.

FIG. 12 is a plan view illustrating a thin film transistor structure according to one embodiment of the present disclosure.

FIG. 13 is a cross-sectional view illustrating a thin film transistor structure along the F-F′ line illustrated in FIG. 12.

FIG. 14A and FIG. 14B are graphs showing the voltage distribution results of dual gate thin film transistors according to comparative examples and embodiments.

FIG. 15 is a graph showing the amount of deterioration according to stress time of the first thin film transistor among the dual gate thin film transistors according to comparative examples and embodiments.

FIG. 16 is a graph showing the voltage relationship between the first thin film transistor and second thin film transistor according to the thickness of the insulating layer of the second thin film transistor among the dual gate thin film transistors according to an embodiment of the present disclosure.

FIG. 17 is an equivalent circuit diagram of a thin film transistor according to one embodiment of the present disclosure.

FIG. 18 is a plan view illustrating a thin film transistor structure according to one embodiment of the present disclosure.

FIG. 19 is a cross-sectional view illustrating a thin film transistor structure along the line G-G′ shown in FIG. 18.

FIG. 20 is a graph showing the voltage distribution results of a dual gate thin film transistor according to a comparative example and an embodiment.

FIG. 21 is an equivalent circuit diagram of a thin film transistor according to one embodiment of the present disclosure.

FIG. 22 is a plan view illustrating a thin film transistor structure according to one embodiment of the present disclosure.

FIG. 23 is a cross-sectional view illustrating a thin film transistor structure along the H-H′ line illustrated in FIG. 22.

FIG. 24 is a graph showing the voltage distribution results of a dual gate thin film transistor according to a comparative example and an embodiment.

FIG. 25 is a schematic diagram illustrating the configuration of a display device according to one embodiment of the present disclosure.

FIG. 26 is an equivalent circuit diagram illustrating a stage configuration of a gate driving circuit according to one embodiment of the present disclosure.

FIG. 27 is an equivalent circuit diagram illustrating a pixel circuit configuration according to one embodiment of the present disclosure.

### DETAILED DESCRIPTION

The advantages and features of this specification, and the methods for achieving them, will become clearer with reference to the embodiments described in detail below together with the accompanying drawings. However, this specification is not limited to the embodiments disclosed below, but may be implemented in various different forms. These embodiments are provided solely to ensure that the disclosure of this specification is complete and to fully inform those skilled in the art of the scope of the invention, and this specification is defined solely by the scope of the claims.

The shapes, sizes, ratios, angles, numbers, etc. disclosed in the drawings for explaining the embodiments of this specification are illustrative and are not limited to the matters illustrated in this specification. Like reference numerals refer to like components throughout the specification. In addition, in describing this specification, if a detailed description of a related known technology is judged to unnecessarily obscure the gist of this specification, the detailed description thereof will be omitted. When “includes,” “has,” “consists of,” etc. are used in this specification, other parts may be added unless “only” is used. When a component is expressed in the singular, it includes a plural unless specifically stated otherwise.

When interpreting a component, it is interpreted as including the error range even if there is no separate explicit description of the error range.

When describing a positional relationship, for example, when the positional relationship between two parts is described as “on,” “above,” “below,” “next to,” etc., one or more other parts may be located between the two parts, unless, for example, “right” or “directly” is used.

When describing a temporal relationship, if the temporal continuity is described as “after,” “continuously,” “next to,” or “before,” it can include non-continuous cases as long as “immediately” or “directly” is not used.

While terms like “first” and “second” are used to describe various components, these components are not limited by these terms. These terms are used merely to distinguish one component from another. Thus, a “first” component referred to below may also be a “second” component within the technical scope of this specification.

When describing components of this specification, terms such as first, second, A, B, a, b, etc. may be used. These terms are only intended to distinguish the components from other components, and the nature, order, sequence, or number of the components are not limited by the terms. When a component is described as being “connected,” “coupled,” or “connected” to another component, it should be understood that the component may be directly connected or connected to the other component, but that other components may also be “interposed” between each component that is indirectly connected or connected without any specific explicit description. “At least one” should be understood to include any combination of one or more of the associated components. For example, “at least one of the first, second, and third components” could be understood to include not only the first, second, or third components, but also any combination of two or more of the first, second, and third components.

The individual features of the various embodiments of this specification may be partially or wholly combined or combined with each other, and may be technically linked and operated in various ways, and each embodiment may be implemented independently of each other or may be implemented together in a related relationship.

Hereinafter, preferred embodiments will be described with reference to the attached drawings. The scale of the components depicted in the drawings is different from the actual scale for convenience of explanation, and is therefore not limited to the scale depicted in the drawings.

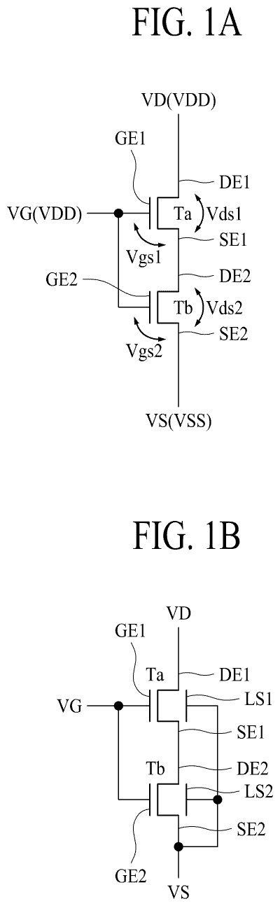

FIG. 1A and FIG. 1B are equivalent circuit diagrams of a thin film transistor according to one embodiment of the present disclosure.

Referring to FIG. 1A and FIG. 1B, a thin film transistor according to one embodiment may have a dual gate structure and include first thin film transistor and second thin film transistor Ta-Tb connected in series.

The first thin film transistor Ta may include a gate electrode GE1, a drain electrode DE1, and a source electrode SE1, and the second thin film transistor Tb may include a gate electrode GE2, a drain electrode DE2, and a source electrode SE2. The source electrode SE1 of the first thin film transistor Ta and the drain electrode DE2 of the second thin film transistor Tb may be connected in series. The first thin film transistor and second thin film transistor Ta and Tb may have a dual gate structure in which the gate electrodes GE1 and GE2 are connected.

Referring to FIG. 1B, a dual gate thin film transistor Ta-Tb according to one embodiment may further include a light shielding electrodes LS1 and LS2 overlapping the gate electrodes GE1 and GE2. The light shielding electrodes LS1 and LS2 may be connected to the source electrode SE2 of the second thin film transistor Tb.

According to one embodiment, a dual gate thin film transistor Ta-Tb may have a diode structure in which a gate electrodes GE1 and GE2 is connected to a drain electrode DE1 of a first thin film transistor Ta.

A dual gate thin film transistor Ta and Tb may be driven in a turn-on state by applying a high-potential power supply voltage VDD as a gate voltage VG and a drain voltage VD, and by applying a low-potential power supply voltage VSS as a source voltage VS.

The drain source voltage Vds applied to the dual gate thin film transistor Ta-Tb is divided into the drain source voltages Vds1 and Vds2 of the first thin film transistor and second thin film transistor Ta and Tb, so that the dual gate thin film transistor Ta and Tb can reduce the High Drain Current Stress (HDCS) caused by the application of a high-potential power supply voltage VDD.

By a high-potential power supply voltage VDD applied to the gate electrode GE1 and the drain electrode DE1, the first thin film transistor Ta can operate in saturation mode (Saturation Mode, Vgs1=Vds1, Vgs1−Vth<Vds1), and the second thin film transistor Tb can operate in linear mode (Linear Mode, Vgs2−Vth>Vds2).

The drain source voltage Vds1 applied to the first thin film transistor Ta in saturation mode may be distributed to a greater extent than the drain source voltage Vds2 applied to the second thin film transistor Tb in linear mode. As the driving time (stress time) increases, the deterioration (Vth shift) of the first thin film transistor Ta in saturation mode may become greater than the deterioration (Vth shift) of the second thin film transistor Tb in linear mode, and as a result, the deterioration (Vth shift) of the dual gate thin film transistors Ta-Tb may become greater.

In order to reduce the deterioration of the first thin film transistor Ta, the dual gate thin film transistor Ta-Tb according to one embodiment may have a heterogeneous resistance structure that can increase the voltage Vds2 distributed to the second thin film transistor Tb and decrease the voltage Vds1 distributed to the first thin film transistor Ta. The dual gate thin film transistor Ta-Tb according to one embodiment may have a heterogeneous resistance structure in which the gate active capacitance (Cox_b, FIG. 3) of the second thin film transistor Tb is smaller than the gate active capacitance (Cox_a, FIG. 3) of the first thin film transistor Ta, so that the resistance of the second thin film transistor Tb is larger than the resistance of the first thin film transistor Ta.

The heterogeneous resistance structure of a dual gate thin film transistor according to one embodiment of the present invention will be specifically described with reference to FIG. 3 to FIG. 13.

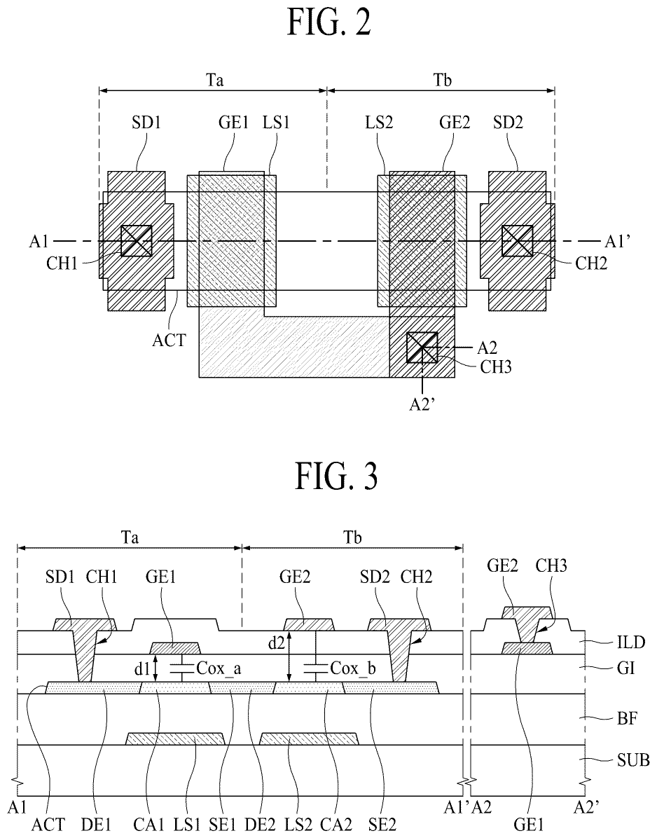

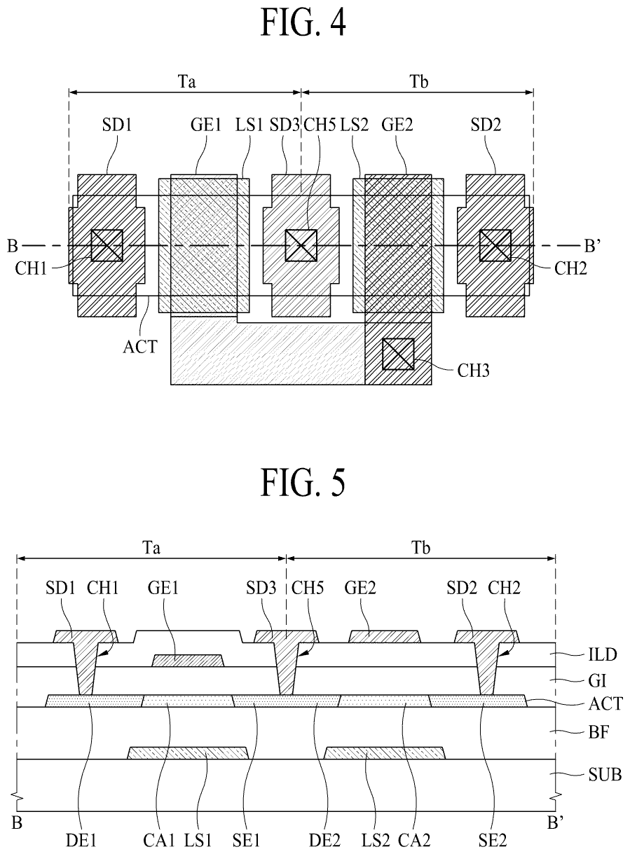

FIG. 2 is a plan view illustrating a thin film transistor structure according to one embodiment of the present disclosure, FIG. 3 is a cross-sectional view illustrating a thin film transistor structure along lines A1-A1′ and A2-A2′ illustrated in FIG. 2, FIG. 4 is a plan view illustrating a thin film transistor structure according to one embodiment of the present disclosure, and FIG. 5 is a cross-sectional view illustrating a thin film transistor structure along line B-B′ illustrated in FIG. 4.

Referring to FIG. 2 to FIG. 5, the first and second thin film transistors Ta and Tb constituting a dual gate thin film transistor according to an embodiment may have a heterogeneous capacitance structure, that is, a heterogeneous resistance structure, in which the gate electrodes GE1 and GE2 are disposed in different layers so that a spacing between the gate electrodes GE1 and GE2 and the active layer ACT is different.

The first thin film transistor Ta may include a first light shielding electrode LS1 on a substrate SUB, a buffer layer BF covering the first light shielding electrode LS1, an active layer ACT on the buffer layer BF, a gate insulating layer GI covering the active layer ACT, a first gate electrode GE1 on the gate insulating layer GI, a first drain electrode DE1 and a first source electrode SE1 provided as a conductorized part facing in a first direction (channel length direction) with a first channel part CA1 interposed therebetween in the active layer ACT.

The second thin film transistor Tb may include a second light shielding electrode LS2 on a substrate SUB, a buffer layer BF covering the second light shielding electrode LS2, an active layer ACT on the buffer layer BF, a gate insulating layer GI covering the active layer ACT, an interlayer insulating layer ILD on the gate insulating layer GI, a gate electrode GE2 on the interlayer insulating layer ILD, a second drain electrode DE2 and a second source electrode SE2 provided as a conductorized part facing the first direction (channel length direction) with a second channel part CA2 interposed therebetween in the active layer ACT.

The first gate electrode GE1 of a first thin film transistor Ta and a second gate electrode GE2 of a second thin film transistor Tb may be connected through a contact hole CH3 penetrating an interlayer insulating layer ILD. The first gate electrode GE1 may extend in a first direction (channel length direction) to overlap with the second gate electrode GE2, and the first gate electrode and second gate electrodes GE1 and GE2 may be connected through the contact hole CH3 at the overlapping portion.

The first source electrode SE1 of the first thin film transistor Ta and the second drain electrode DE2 of the second thin film transistor Tb may be formed as an integral body by sharing the conductorized part of the active layer ACT between the first channel part and second channel parts CA1 and CA2.

A dual gate thin film transistor Ta-Tb may further include a drain connection electrode SD1 and a source connection electrode SD2 respectively connected to a first drain electrode DE1 and a second source electrode SE2 through first and second contact holes CH1 and CH2 respectively penetrating the interlayer insulating layer ILD and the gate insulating layer GI, and disposed on an interlayer insulating layer ILD.

Referring to FIG. 4 and FIG. 5, the dual gate thin film transistor Ta-Tb may further include a connecting electrode SD3. The connecting electrode SD3 is disposed on an interlayer insulating layer ILD and is connected to a conductorized part of an active layer ACT in which a first source electrode SE1 and a second drain electrode DE2 are integrated through a contact hole CH5 penetrating the interlayer insulating layer ILD and the gate insulating layer GI, thereby reducing the resistance of the conductorized part.

The active layer ACT may have a structure in which channel parts CA1 and CA2 having semiconductor characteristic and a conductorized part having conductive characteristic are integrally formed. The conductorized part may be a region in which the active layer ACT is selectively conductorized by ion implantation, plasma treatment, heat treatment, or the like. The conductorized part of the active layer ACT may include a first drain electrode DE1 and a first source electrode SE1 of a first thin film transistor Ta, and a second drain electrode DE2 and a second source electrode SE2 of a second thin film transistor Tb. The first drain electrode DE1 may be expressed as a first conductorized part, the first source electrode SE1 and the second drain electrode DE2 may be expressed as a second conductorized part, and the second source electrode SE2 may be expressed as a third conductorized part.

The active layer ACT may have a structure in which the length in the first direction (channel length direction) is longer than the width in the second direction (channel width direction). In the active layer ACT, a first drain electrode DE1, a first channel part CA1, a first source electrode SE1, a second drain electrode DE2, a second channel part CA2, and a second source electrode SE2 may be disposed in parallel in the first direction (channel length direction).

The drain connection electrode SD1, the first gate electrode GE1, the second gate electrode GE2, and the source connection electrode SD2 may be spaced apart from each other in the first direction (channel length direction) and arranged parallel to each other in the first direction.

The light shielding electrodes LS1 and LS2 overlap with the channel parts CA1 and CA2, respectively, and can protect the channel parts CA1 and CA2 by blocking light incident through the substrate SUB. The light shielding electrodes LS1 and LS2 can overlap with the gate electrodes GE1 and GE2, respectively. The channel parts CA1 and CA2 may be connected as an integral body and may have a source contact structure that is connected to the source connection electrode SD2 through a contact hole penetrating a plurality of insulating layers ILD and GI. The light shielding electrodes LS1 and LS2 may be omitted.

The first gate electrode GE1 of the first thin film transistor Ta may be disposed on a gate insulating layer GI and overlap with the first channel part CA1 with the gate insulating layer GI interposed therebetween. A second gate electrode GE2 of the second thin film transistor Tb may be disposed on an interlayer insulating layer ILD and overlap with the second channel part CA2 with the gate insulating layer GI and the interlayer insulating layer ILD interposed therebetween.

The gate insulating layer GI and interlayer insulating layer ILD may be expressed as the first and second gate insulating layers.

The gate electrode GE1 and the active layer ACT of the first thin film transistor Ta may have a gap d1 corresponding to the thickness of one insulating layer GI, and the gate electrode GE2 and the active layer ACT of the second thin film transistor Tb may have a gap (d2, d2>d1) corresponding to the thickness of two insulating layers GI, ILD.

Accordingly, in the dual gate thin film transistor according to one embodiment, a second capacitance Cox_b between the gate electrode GE2 and the active layer ACT of the second thin film transistor Tb may be smaller than a first capacitance Cox_a between the gate electrode GE1 and the active layer ACT of the first thin film transistor Ta. Accordingly, a resistance of the second thin film transistor Tb may be larger than a resistance of the first thin film transistor Ta.

Accordingly, the voltage Vds2 distributed to the second thin film transistor Tb increases and the voltage Vds1 distributed to the first thin film transistor Ta decreases, so that the difference between the voltages Vds1 and Vds2 distributed to the first thin film transistor and second thin film transistors Ta and Tb may be reduced. As a result, the stress and deterioration of the first thin film transistor Ta in saturation mode may be reduced, and further, the overall stress and deterioration of the dual gate thin film transistors Ta and Tb may be reduced.

The buffer layer BF, gate insulating layer GI, and interlayer insulating layer ILD may be expressed as multiple insulating layers. Each of the multiple insulating layers may have a single layer or multi-layer including an insulating material. The buffer layer BF and gate insulating layer GI may be formed of silicon oxide (SiOx) or aluminum oxide (Al₂O₃) with low hydrogen content. The interlayer insulating layer ILD may have a single layer or multi-layer including at least one of silicon oxide (SiOx) and silicon nitride (SiNx).

The active layer ACT may include any one of an amorphous silicon semiconductor material, a polysilicon semiconductor material, and a metal oxide semiconductor material. For example, the semiconductor layer ACT may include at least one of an IGZO (InGaZnO) based, IGO (InGaO) based, IGZTO (InGaZnSnO) based, GZTO (GaZnSnO) based, GZO (GaZnO) based, GO (GaO) based, TO (SnO) based, ITO (InSnO) based, ITZO (InSnZnO) based, IZO based, ZO (ZnO) based, IO (IO) based, InO (InO) based, ZnO based, and FIZO (FeInZnO) based metal oxide semiconductor material. The active layer ACT may have a single layer structure or a multi-layer in which at least two oxide semiconductor layers are stacked.

The light shielding electrodes LS1 and LS2 may be formed of a first metal layer (light shielding metal layer). The gate electrode GE1 may be formed of a second metal layer (gate metal layer). The gate electrode GE2 and the drain connection electrode SD1 and the source connection electrode SD2 may be formed of a third metal layer (source/drain metal layer). Each of the first, second, and third metal layers may have a single layer structure including at least one of aluminum (Al), molybdenum (Mo), chromium (Cr), tantalum (Ta), neodymium (Nd), titanium (Ti), copper (Cu), gold (Au), silver (Ag), and alloys thereof, or may have a multi-layer structure in which at least two metal layers are stacked.

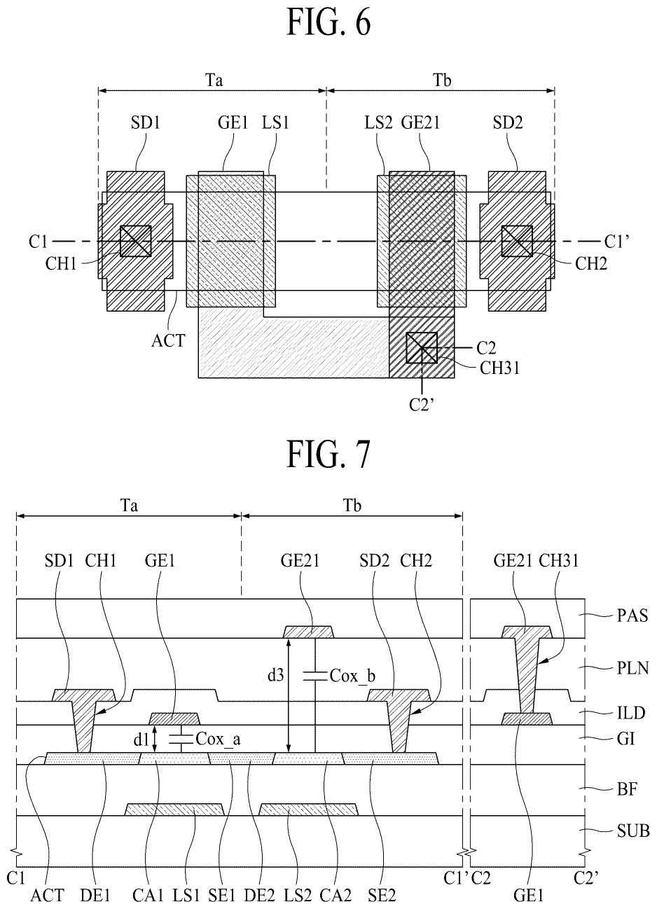

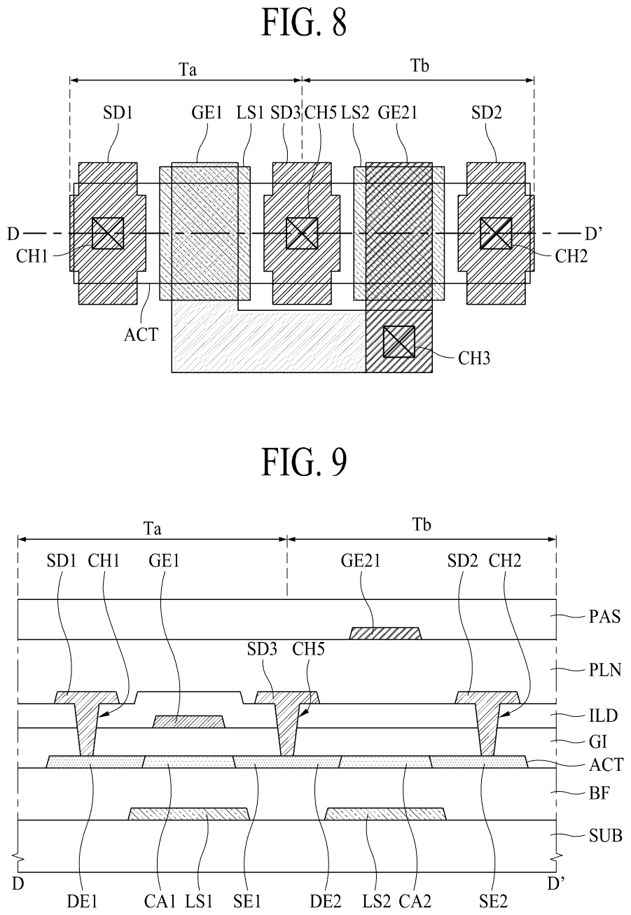

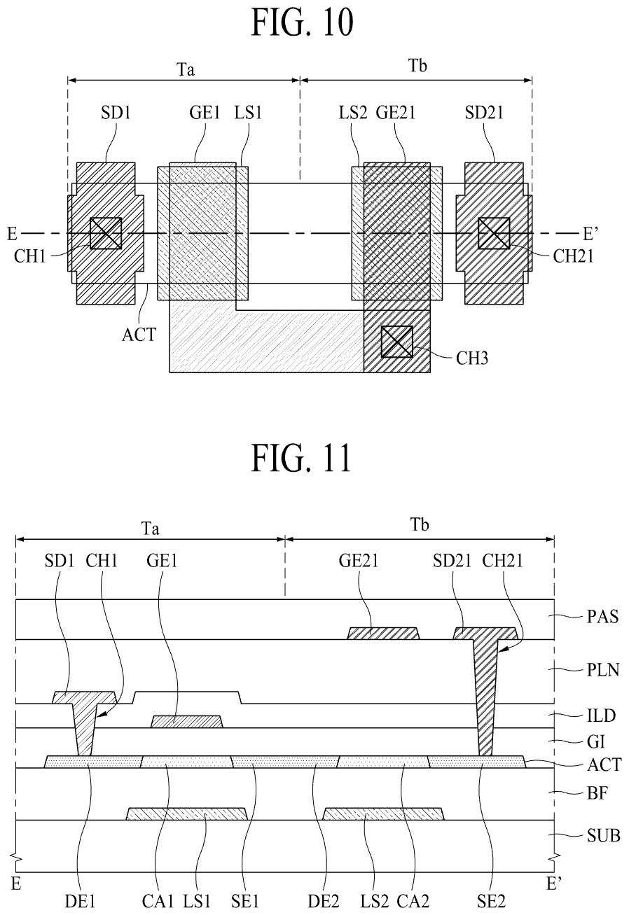

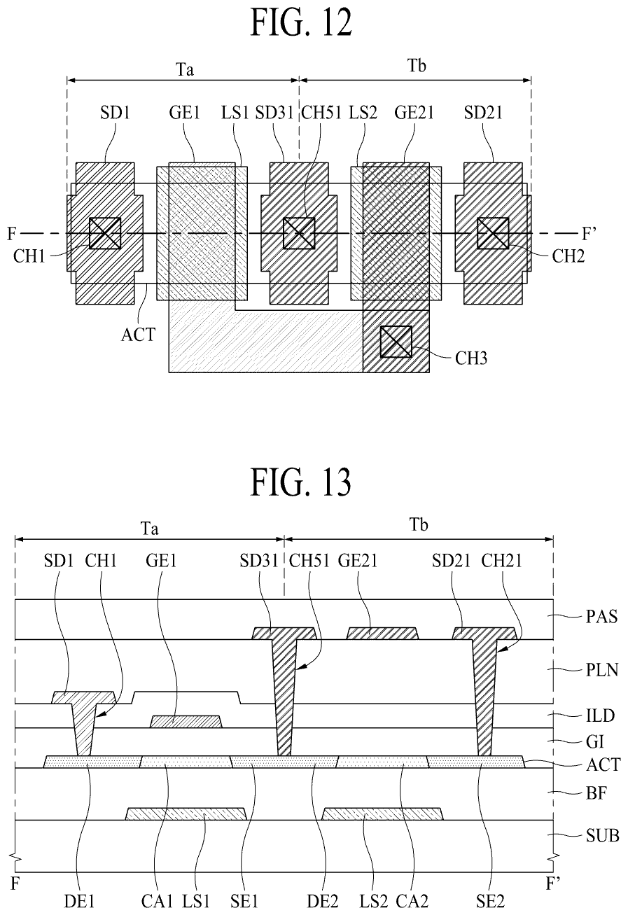

FIG. 6 is a plan view illustrating a thin film transistor structure according to an embodiment of the present disclosure, FIG. 7 is a cross-sectional view illustrating a thin film transistor structure along lines C1-C1′ and C2-C2′ illustrated in FIG. 6, FIG. 8 is a plan view illustrating a thin film transistor structure according to an embodiment of the present disclosure, and FIG. 9 is a cross-sectional view illustrating a thin film transistor structure along line D-D′ illustrated in FIG. 8. FIG. 10 is a plan view illustrating a thin film transistor structure according to an embodiment of the present disclosure, and FIG. 11 is a cross-sectional view illustrating a thin film transistor structure along line E-E′ illustrated in FIG. 10, and FIG. 12 is a plan view illustrating a thin film transistor structure according to an embodiment of the present disclosure, and FIG. 13 is a cross-sectional view illustrating a thin film transistor structure along line F-F′ illustrated in FIG. 12.

The dual gate thin film transistor according to one embodiment illustrated in FIG. 6 to FIG. 9 has a difference in the arrangement position of the gate electrode GE21 of the second thin film transistor Tb compared to the dual gate thin film transistor according to one embodiment illustrated in FIG. 2 to FIG. 5.

The dual gate thin film transistor according to an embodiment illustrated in FIG. 10 to FIG. 13 has a difference in that the arrangement positions of the gate electrode GE21, the source connection electrode SD21, and the connection electrode SD31 of the second thin film transistor Tb are different from the dual gate thin film transistor according to an embodiment illustrated in FIG. 2 to FIG. 5.

Therefore, FIG. 6 to FIG. 13 will focus on explaining the configurations that are different from FIG. 2 to FIG. 5, and will omit explanations of overlapping configurations.

Referring to FIG. 6 to FIG. 13, a dual gate thin film transistor according to one embodiment may further include a planarization layer PLN covering a drain connection electrode SD1 and a source connection electrode SD2 on an interlayer insulating layer ILD, and a passivation layer PAS on the planarization layer PLN. A second gate electrode GE21 of a second thin film transistor Tb may be disposed on the planarization layer PLN, and may be connected to a first gate electrode GE1 of a first thin film transistor Ta through a contact hole CH31 penetrating the planarization layer PLN and the interlayer insulating layer ILD.

The planarization layer PLN may include an organic insulating material, and the passivation layer PAS may include an inorganic insulating material.

Referring to FIG. 10 to FIG. 13, the source connection electrode SD21 of the second thin film transistor Tb may be disposed on the planarization layer PLN in the same method as the second gate electrode GE21. The source connection electrode SD21 may be connected to the second source electrode SE2 of the active layer ACT through a contact hole CH21 penetrating the planarization layer PLN, the interlayer insulating layer ILD, and the gate insulating layer GI.

Referring to FIG. 12 and FIG. 13, the connection electrode SD31 may be disposed on the planarization layer PLN in the same method as the second gate electrode GE21 and the source connection electrode SD21. The connection electrode SD31 may be connected to the first source electrode SE1 and the second drain electrode DE2 of the active layer ACT through a contact hole CH51 penetrating the planarization layer PLN, the interlayer insulating layer ILD, and the gate insulating layer GI.

The gate insulating layer GI, interlayer insulating layer ILD, and planarization layer PLN may be expressed as the first, second, and third insulating layers.

Referring to FIG. 6 to FIG. 13, the gate electrode GE1 and the active layer ACT of the first thin film transistor Ta may have a gap d1 corresponding to the thickness of one insulating layer GI, and the gate electrode GE21 and the active layer ACT of the second thin film transistor Tb may have a gap (d3, d3>d1) corresponding to the thickness of three insulating layers GI, ILD and PLN.

Accordingly, in the dual gate thin film transistor according to one embodiment, a second capacitance Cox_b between the gate electrode GE21 and the active layer ACT of the second thin film transistor Tb may be smaller than a first capacitance Cox_a between the gate electrode GE1 and the active layer ACT of the first thin film transistor Ta. Accordingly, the resistance of the second thin film transistor Tb may be larger than the resistance of the first thin film transistor Ta.

Accordingly, the voltage Vds1 distributed to the first thin film transistor Ta may be reduced, thereby reducing the stress and deterioration of the first thin film transistor Ta, and as a result, the overall stress and deterioration of the dual gate thin film transistor Ta-Tb may be reduced.

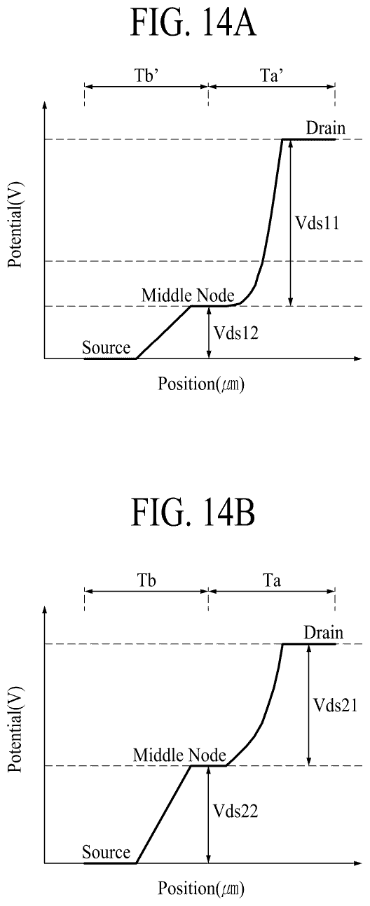

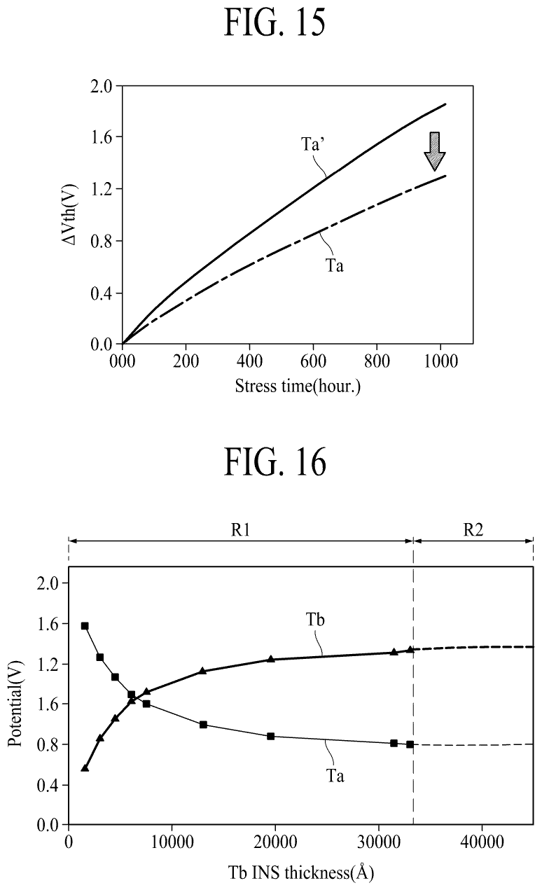

FIG. 14A is a graph showing the voltage distribution result of a dual gate thin film transistor according to a comparative example, FIG. 14B is a graph showing the voltage distribution result of a dual gate thin film transistor according to an embodiment, and FIG. 15 is a graph showing the amount of deterioration according to stress time of a first thin film transistor among dual gate thin film transistors according to a comparative example and an embodiment.

FIG. 14A and FIG. 14B show the potential V that changes depending on the position (μ) of the first thin film transistors and second thin film transistors Ta′/Tb′ and Ta/Tb. FIG. 15 shows the amount of deterioration (ΔVth, Vth shift amount) of the first thin film transistors Ta′ and Ta that increases depending on the stress time.

Referring to FIG. 14A, a dual gate thin film transistor according to a comparative example may include first thin film transistor and second thin film transistor Ta′ and Tb′ having the same structure, and when a turn-on operation is performed by application of a high-potential power supply voltage VDD, it may be seen that the voltage Vds11 distributed to the first thin film transistor Ta′ operating in a saturated mode is greater than the voltage Vds12 distributed to the second thin film transistor Tb′ operating in a linear mode.

Referring to FIG. 14B, a dual gate thin film transistor according to one embodiment may include first thin film transistor and second thin film transistors Ta and Tb of a heterogeneous structure having different gate active capacitances as shown in FIG. 2 to FIG. 13, and when a turn-on operation is performed by applying a high-potential power supply voltage VDD, it may be seen that the voltage Vds21 distributed to the first thin film transistor Ta in the saturation mode is reduced compared to the distribution voltage Vds11 of the comparative example, and the drain source voltage Vds22 distributed to the second thin film transistor Tb in the linear mode is increased compared to the distribution voltage Vds12 of the comparative example.

Accordingly, referring to FIG. 15, it may be seen that the amount of deterioration (ΔVth, Vth shift) according to stress time of the first thin film transistor Ta according to the embodiment is reduced compared to the amount of deterioration (ΔVth, Vth shift) according to stress time of the first thin film transistor Ta′ according to the comparative example. As a result, the dual gate thin film transistor according to the embodiment can reduce the overall stress and deterioration compared to the comparative example.

FIG. 16 is a graph showing the relationship between the gate insulation layer thickness and the distribution voltage of the first thin film transistor and second thin film transistor in a dual gate thin film transistor according to one embodiment of the present disclosure.

Referring to FIG. 16, it may be seen that as the thickness of the plurality of insulating layers INS between the gate electrode GE2 and the active layer ACT of the second thin film transistor Tb increases, the voltage distributed to the second thin film transistor Tb increases, and the voltage distributed to the first thin film transistor Ta decreases. It may be confirmed that when the thickness of the plurality of insulating layers INS between the gate electrode GE2 and the active layer ACT of the second thin film transistor Tb is 7000 Å (GI thickness of Ta=1500 Å), the distributed voltage of the second thin film transistor Tb becomes greater than the distributed voltage of the first thin film transistor Ta.

As the thickness of the multiple insulating layers INS between the gate electrode GE2 and the active layer ACT of the second thin film transistor Tb increases, the capacitance Cox_b between the gate electrode GE2 and the active layer ACT decreases, thereby reducing the current Ids.

According to one embodiment, the thickness of the plurality of insulating layers INS between the gate electrode GE2 and the active layer ACT of the second thin film transistor Tb may be greater than the thickness (1500 Å=0.15 μm) of the gate insulating layer GI of the first thin film transistor Ta and may be less than the maximum thickness (3.3 μm, 22 times the Ta GI thickness) of the first region R1 in which the reliability improvement effect is greater than the reduction in current Ids of the second thin film transistor Tb.

In the dual gate thin film transistor according to one embodiment, the first thin film transistor Ta may have a first thickness d1 corresponding to the gate insulating layer GI between the gate electrode GE1 and the active layer ACT. The second thin film transistor Tb may have a second thickness d2 including the gate insulating layer GI and the interlayer insulating layer ILD between the gate electrode GE2 and the active layer ACT, or may have a third thickness d3 including the gate insulating layer GI, the interlayer insulating layer ILD, and the planarization layer PLN.

Even though the second thin film transistor Tb includes a relatively thick planarization layer PLN of about 2.6 μm between the gate electrode GE2 and the active layer ACT, together with a gate insulating layer GI and an interlayer insulating layer ILD, it can operate normally because the third thickness d3 of the three insulating layers is smaller than the maximum thickness (3.3 μm) of the first region R1.

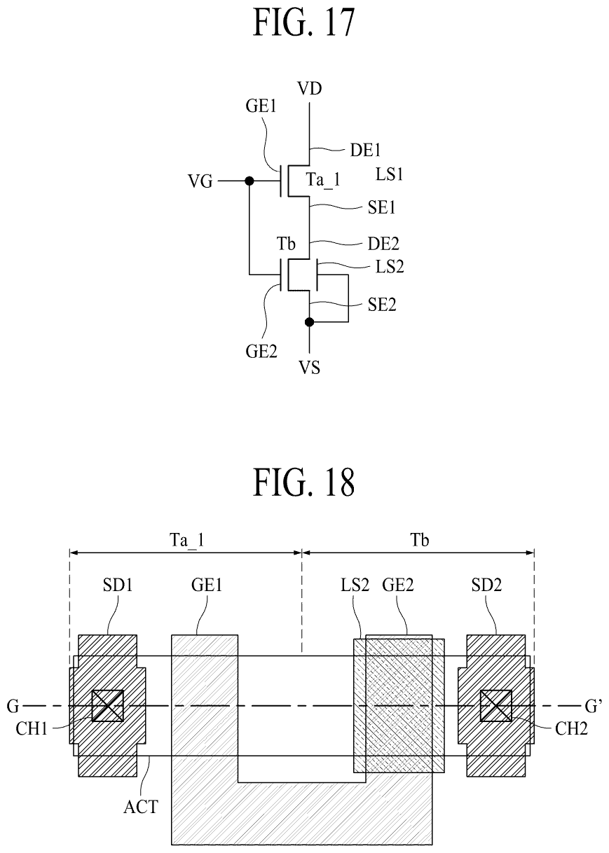

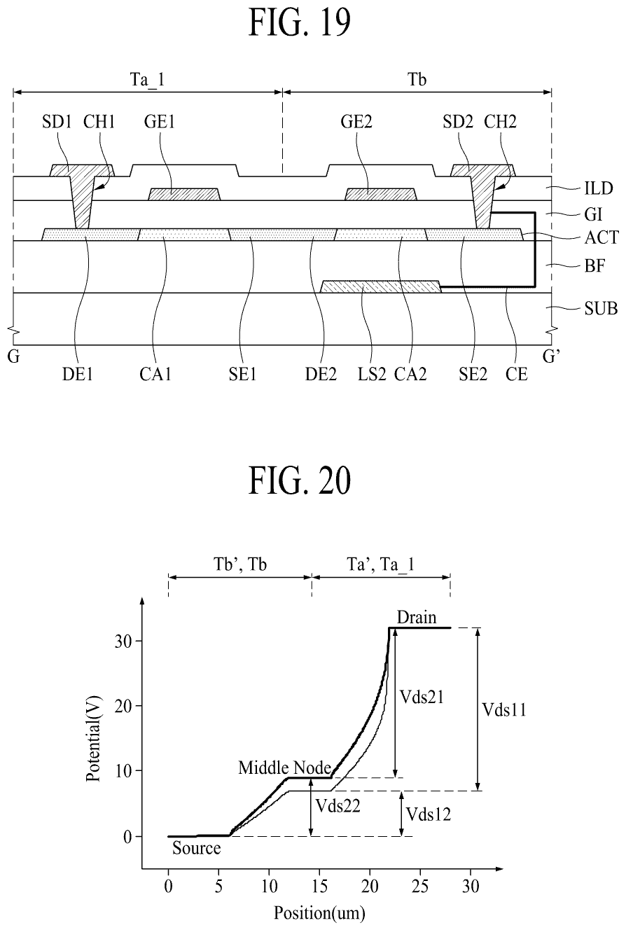

FIG. 17 is an equivalent circuit diagram of a thin film transistor according to one embodiment of the present disclosure, FIG. 18 is a plan view illustrating a thin film transistor structure according to one embodiment of the present disclosure, FIG. 19 is a cross-sectional view illustrating a thin film transistor structure along the line G-G′ illustrated in FIG. 18, and FIG. 20 is a graph comparing voltage distribution results of dual gate thin film transistors according to a comparative example and one embodiment.

Referring to FIG. 17 to FIG. 19, a dual gate thin film transistor according to one embodiment includes first thin film transistor and second thin film transistor Ta_1 and Tb that share gate electrodes GE1 and GE2 and are connected in series, and may have a heterogeneous resistance structure in which the resistance of the first thin film transistor Ta_1 is smaller than the resistance of the second thin film transistor Tb. Descriptions of configurations that overlap with those of the previously described embodiments will be omitted or briefly mentioned.

The first thin film transistor Ta_1 may include a first gate electrode GE1, a first channel part CA1 of an active layer ACT, a first drain electrode DE1 and a first source electrode SE1 respectively connected to both sides of the first channel part CA1. The second thin film transistor Tb may include a gate electrode GE2, a second channel part CA2 of the active layer ACT, a second drain electrode DE2 and a second source electrode SE2 respectively connected to both sides of the second channel part CA2, and a light shielding electrode LS2 connected to the second source electrode SE2. The first gate electrode and second gate electrode GE1 and GE2 may be disposed on a gate insulating layer GI and may be formed integrally. The first source electrode SE1 and the second drain electrode DE2 may be formed integrally in a conductorized part between the first channel part and second channel part CA1 and CA2 of the active layer ACT.

According to one embodiment, a dual gate thin film transistor may have a diode structure in which gate electrodes GE1 and GE2 are connected to a drain electrode DE1 of a first thin film transistor Ta_1.

The first thin film transistor Ta_1 does not include a light shielding electrode, and the second thin film transistor Tb includes a light shielding electrode LS2 of a source contact structure, so that the resistance of the first thin film transistor Ta_1 may be reduced compared to the resistance of the second thin film transistor Tb.

Accordingly, the voltage Vds1 distributed to the first thin film transistor Ta_1 may decrease, the voltage Vds2 distributed to the second thin film transistor Tb may increase, and the difference between the voltages Vds1, Vds2 distributed to the first thin film transistor and second thin film transistor Ta_1, Tb may decrease.

Referring to FIG. 20, a dual gate thin film transistor according to a comparative example may include a first thin film transistor and a second thin film transistor Ta′ and Tb′ having the same structure, and when a turn-on operation is performed by application of a high-potential power supply voltage VDD, it may be seen that the voltage Vds11 distributed to the first thin film transistor Ta′ operating in a saturated mode is greater than the voltage Vds12 distributed to the second thin film transistor Tb′ operating in a linear mode.

On the other hand, the dual gate thin film transistor according to one embodiment may include a first thin film transistor and a second thin film transistor Ta_1 and Tb of a heterogeneous resistance structure as shown in FIG. 17 to FIG. 19, and when the turn-on operation is performed by applying a high-potential power supply voltage VDD, it may be seen that the voltage Vds21 distributed to the first thin film transistor Ta_1 in the saturation mode is reduced compared to the distribution voltage Vds11 of the comparative example, and the drain source voltage Vds22 distributed to the second thin film transistor Tb in the linear mode is increased compared to the distribution voltage Vds12 of the comparative example.

As a result, the stress and degradation of the first thin film transistor Ta_1 in saturation mode may be reduced, and further, the overall stress and degradation of the dual gate thin film transistor Ta_1-Tb may be reduced.

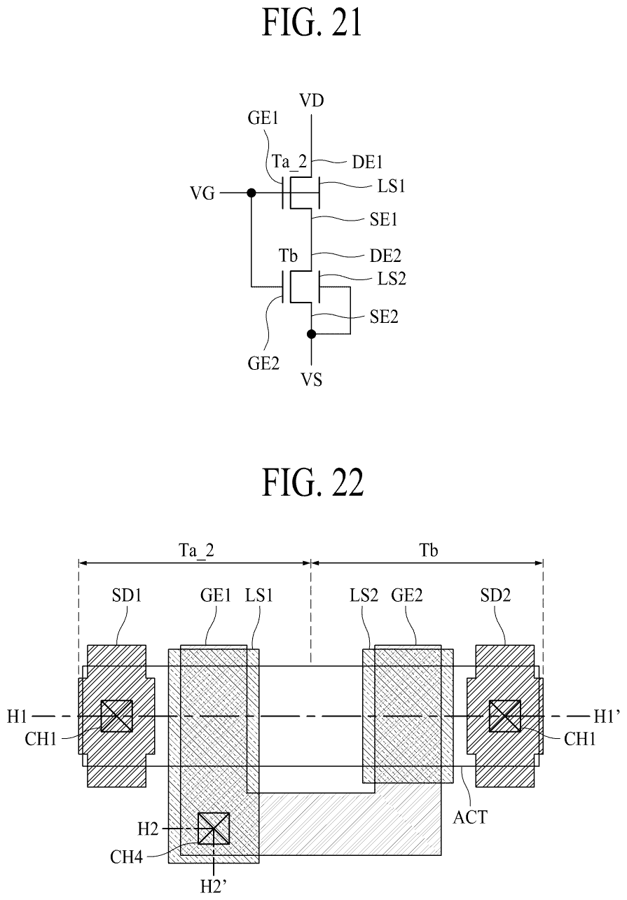

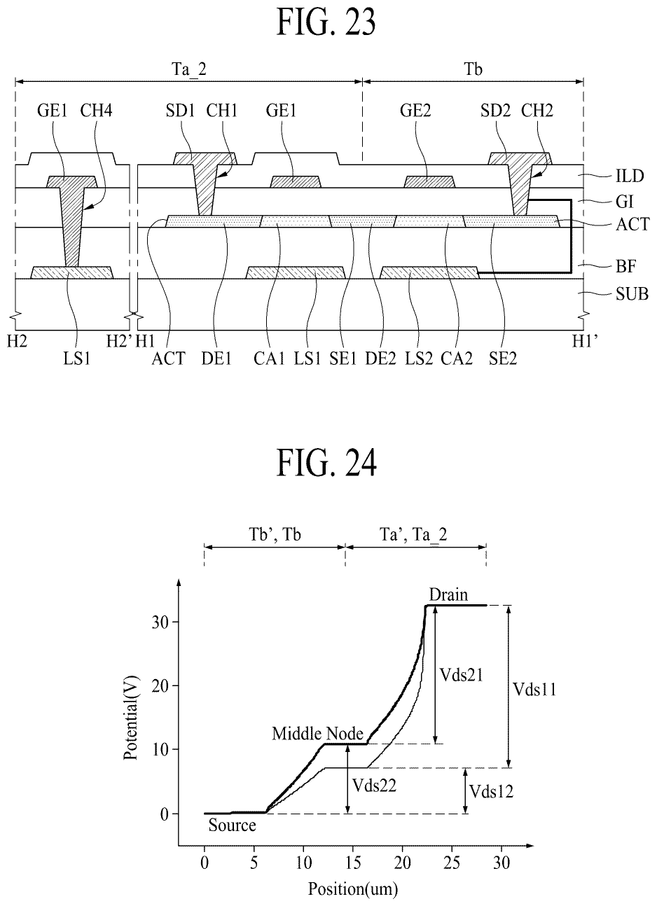

FIG. 21 is an equivalent circuit diagram of a thin film transistor according to one embodiment of the present disclosure, FIG. 22 is a plan view illustrating a thin film transistor structure according to one embodiment of the present disclosure, FIG. 23 is a cross-sectional view illustrating a thin film transistor structure along lines H1-H1′ and H2-H2 illustrated in FIG. 22, and FIG. 24 is a graph comparing voltage distribution results of dual gate thin film transistors according to a comparative example and one embodiment.

The dual gate thin film transistor Ta_2-Tb according to an embodiment illustrated in FIG. 21 to FIG. 23 has a difference in that the first thin film transistor Ta_2 has a double gate structure including a light shielding electrode LS1 connected to the gate electrode GE1, compared to the dual gate thin film transistor Ta_1, Tb according to an embodiment illustrated in FIG. 17 to FIG. 19. Therefore, descriptions of overlapping components with those of the previously described embodiments will be omitted or briefly mentioned.

The first thin film transistor Ta_2 may include a first gate electrode GE1, a first drain electrode DE1, a first source electrode SE1, and a first light shielding electrode LS1 connected to the first gate electrode GE1. The second thin film transistor Tb may include a gate electrode GE2, a second drain electrode DE2, a second source electrode SE2, and a light shielding electrode LS2 connected to the second source electrode SE2. The first gate electrode and second gate electrode GE1, GE2 may be disposed on a gate insulating layer GI and formed as an integral body.

The first light shielding electrode LS1 and a first gate electrode GE1 overlapped with a first channel part CA1 may extend in the second direction (channel width direction) and may overlap with a gate insulating layer GI and a buffer layer BF in a region that does not overlap with the active layer ACT. The first gate electrode GE1 may be connected to the first light shielding electrode LS1 through a contact hole CH4 penetrating the gate insulating layer GI and the buffer layer BF.

The first thin film transistor Ta_2 may have a double gate structure in which a first light shielding electrode LS1 and a first gate electrode GE1 are connected, and the second thin film transistor Tb may have a source contact structure in which a second light shielding electrode LS2 and a second source electrode SE2 are connected.

Accordingly, the double-gate thin film transistor Ta_2-Tb according to one embodiment may have a heterogeneous resistance structure in which the resistance of the first thin film transistor Ta_2 is smaller than the resistance of the second thin film transistor Tb. Accordingly, the voltage Vds1 distributed to the first thin film transistor Ta_2 may decrease, the voltage Vds2 distributed to the second thin film transistor Tb may increase, and the difference between the voltages Vds1, Vds2 distributed to the first thin film transistor and second thin film transistor Ta_2, Tb may decrease.

Referring to FIG. 24, a dual gate thin film transistor according to one embodiment may include first thin film transistor and second thin film transistor Ta_2 and Tb of a heterogeneous resistance structure as shown in FIG. 21 to FIG. 23, and when a turn-on operation is performed by applying a high-potential power supply voltage VDD, it may be seen that the voltage Vds21 distributed to the first thin film transistor Ta_2 in the saturation mode is reduced compared to the distribution voltage Vds11 of the comparative example, and the drain source voltage Vds22 distributed to the second thin film transistor Tb in the linear mode is increased compared to the distribution voltage Vds12 of the comparative example.

As a result, the stress and degradation of the first thin film transistor Ta_2 in saturation mode may be reduced, and further, the overall stress and degradation of the dual gate thin film transistor Ta_2-Tb may be reduced.

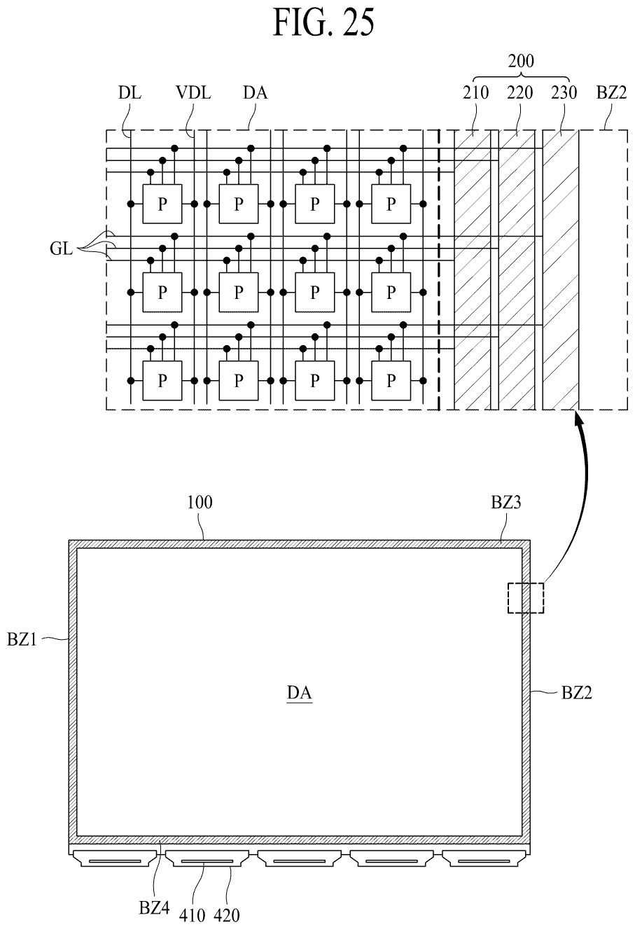

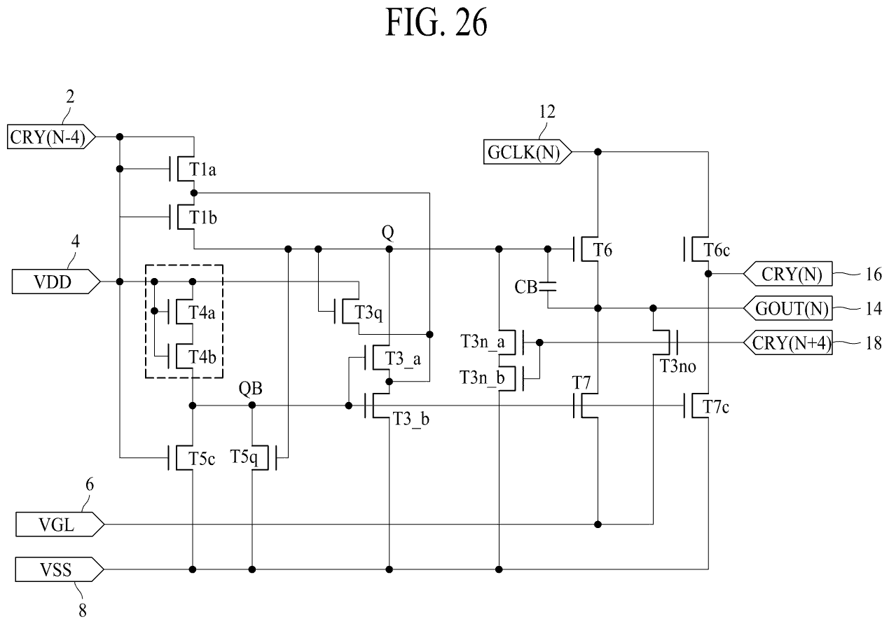

FIG. 25 is a schematic diagram illustrating the configuration of a display device according to one embodiment of the present disclosure, and FIG. 26 is an equivalent circuit diagram illustrating the configuration of each stage of a gate driving circuit according to one embodiment of the present disclosure.

A display device according to one embodiment may be an electroluminescent display. The electroluminescent display device may be any one of an organic light emitting diode (OLED) display device, a quantum-dot light emitting diode (QD) display device, and an inorganic light emitting diode (ILD) display device.

Referring to FIG. 25, a display device according to one embodiment may include a display panel 100, a gate driving circuit 200 built into the display panel 100, and a data driving circuit 410 connected to the display panel 100. The gate driving circuit 200 and the data driving circuit 410 may be expressed as driving circuits.

The display panel 100 may be a rigid display panel or a flexible display panel capable of changing shape, such as a foldable, bendable, rollable, or stretchable display panel.

The display panel 100 can display an image through a pixel array in which subpixels SP are disposed in a matrix form in a display area DA. In one embodiment, the display panel 100 may further include a touch sensor array disposed in the display area DA to sense a user's touch. The subpixels P may include a red subpixel that emits red light, a green subpixel that emits green light, a blue subpixel that emits blue light, and may further include a white subpixel that emits white light. Each subpixel P may include a pixel circuit composed of a light emitting element and a plurality of thin film transistors that independently drive the light emitting element. The display panel 100 may include a plurality of data lines DL, a plurality of gate lines GL, a plurality of power lines VDL, and other signal lines connected to the subpixels P.

The display panel 100 according to one embodiment may further include a touch sensor screen disposed in the display area DA to sense a user's touch.

The gate driving circuit 200 may be disposed in at least one of the bezel areas BZ1 to BZ2 located at the outer portion surrounding the display area DA of the display panel 100. For example, the gate driving circuit 200 may be disposed in at least one of the first and second bezel areas BZ1, BZ2 facing each other with the display area DA interposed therebetween. The gate driving circuit 200 may be built into the display panel 100 in the form of a gate in panel (GIP) formed together with thin film transistors of the display area DA.

The gate driving circuit 200 may include first and second scan driving circuits 210, 220 for driving a plurality of gate lines GL and a light emission control driving circuit 230. The first scan driving circuit 210 may include a plurality of first scan stages for supplying a first scan signal to each of a first group of gate lines among the plurality of gate lines GL. The second scan driving circuit 220 may include a plurality of second scan stages for supplying a second scan signal to each of a second group of gate lines among the plurality of gate lines GL. The light emission control driving circuit 230 may include a plurality of light emission control stages for supplying a light emission control signal to each of a third group of gate lines among the plurality of gate lines GL.

The number of gate lines, the number of scan driving circuits, and the number of light emission control driving circuits connected to the subpixels P of each pixel line are not limited to those shown in FIG. 25, and may be varied in various ways depending on the detailed configuration of the pixel circuit constituting each subpixel P.

The data driving circuit 410 can convert digital data supplied from the timing controller into an analog data voltage and supply the data voltage to each of a plurality of data lines DL of the display panel 100. The data driving circuit 410 includes one or a plurality of ICs (Integrated Circuits), and may be mounted on each circuit film 420 and electrically connected to a pad area disposed in a bezel area BZ4 of the display panel 100 through an anisotropic conductive film (ACF). The circuit film 420 may be any one of a COF (Chip On Film), an FPC (Flexible Printed Circuit), and an FFC (Flexible Flat Cable).

The thin film transistors included in the driving circuit including the gate driving circuit 200 disposed in the display area DA and the bezel area BZ1 to BZ4 of the display panel 100 can use any one of a polysilicon semiconductor, an amorphous silicon semiconductor, and an oxide semiconductor.

In one embodiment, the thin film transistors of the display panel 100 may include at least one of a low temperature poly silicon (LTPS) transistor and an oxide transistor using a metal oxide semiconductor.

The thin film transistors of the display panel 100 according to one embodiment include a dual gate thin film transistor having a heterogeneous resistance structure according to one embodiment described above, so that stress and deterioration of the dual gate thin film transistor may be reduced.

Referring to FIG. 26, each stage of the gate driving circuit may include a set node 2 to which either a start signal VST or a carry output CRY(N−4) of a preceding stage is applied as a set signal, a high-potential power line 4 to which a high-potential power voltage VDD is applied, a first gate-off voltage line 6 to which a first gate-off voltage VGL is applied, a second gate-off voltage line 8 to which a second gate-off voltage VSS is applied, a clock line 12 to which a clock signal GCLK(N) is applied, a gate output line 14 to which a gate output GOUT(N) is applied, a carry output line 16 to which a carry output CRY(N) is applied, and a reset node 18 to which either a reset signal or a carry output CRY(N+4) of a succeeding stage is applied as a reset signal.

The carry output CRY(N) of each stage may be applied as a carry signal to another stage. The gate output GOUT(N) of each stage may be applied as a scan signal to the gate line GL of the display panel 100. The second gate-off voltage VSS used for the carry output CRY(N) may be a voltage lower than the first gate-off voltage VGL used for the gate output GOUT(N).

Each stage of the gate driving circuit according to one embodiment may include a first charging unit and a first discharging unit for charging and discharging a first control node Q, a second charging unit and a second discharging unit for charging and discharging a second control node QB, a first output unit for outputting a gate signal GOUT(N), and a second output unit for outputting a carry signal CRY(N).

The first charging unit may include 1-1 and 1-2 thin film transistors T1a, T1b that are connected in series between a set node 2 and a first control node Q and share a gate electrode connected to the set node 2. The 1-1 and 1-2 thin film transistors T1a, T1b may activate a charging path between the set node 2 and the first control node Q in response to a set signal (a start signal or a carry output CRY(N−4) of a preceding stage) applied to the set node 2. The 1-1 and 1-2 thin film transistors T1a, T1b may charge the first control node Q using a gate-on voltage of the set signal through the activated first charging path. The carry output CRY(N−4) of the preceding stage may be applied from the (N−4)th preceding stage.

The first discharge unit may include a 1-1 discharge unit providing a 1-1 discharge pass of the first control node Q, and a 1-2 discharge unit providing a 1-2 discharge pass of the first control node Q.

The 1-1 discharge unit may include 3-1 and 3-2 thin film transistors T3_a, T3_b that are connected in series between a first control node Q and a second gate-off voltage line VSS and share a gate electrode connected to a second control node QB. The 3-1 and 3-2 thin film transistors T3_a, T3_b may activate a 1-1 discharge path between the first control node Q and the second gate-off voltage line VSS in response to control of the second control node QB. The 3-1 and 3-2 thin film transistors T3_a, T3_b may discharge the voltage of the first control node Q to the second gate-off voltage line VSS through the activated 1-1 discharge path.

The 1-2 discharge unit may include 3-3 and 3-4 thin film transistors T3n_a, T3n_b that are connected in series between the first control node Q and the second gate-off voltage line VSS and share a gate electrode connected to the reset node 18. The 3-3 and 3-4 thin film transistors T3n_a and T3n_b may activate the 1-2 discharge path between the first control node Q and the second gate-off voltage line VSS in response to a reset signal (reset signal or carry output CRY(N+4) of a subsequent stage) applied to the reset node 14. The 3-3 and 3-4 thin film transistors T3n_a and T3n_b may discharge the voltage of the first control node Q to the second gate-off voltage line VSS through the activated 1-2 discharge path.

The second charging unit may include 4-1 and 4-2 thin film transistors T4a and T4b that are connected in series between the high-potential voltage line 4 and the second control node QB and share a gate electrode connected to the high-potential voltage line 4. The 4-1 and 4-2 thin film transistors T4a and T4b are activated by a high-potential power supply voltage VDD applied to the high-potential voltage line 4, thereby charging the second control node QB with the high-potential power supply voltage VDD.

The second discharge unit may include a 2-1 discharge unit providing a 2-1 discharge path of the second control node QB, and a 2-2 discharge unit providing a 2-2 discharge path of the second control node QB.

The 2-1 discharge unit may include a 5-1 thin film transistor T5c having a gate electrode connected to a set node 2 and providing a 2-1 discharge path between a second control node QB and a second gate-off voltage line 8. The 5-1 thin film transistor T5c may activate the 2-1 discharge path between the second control node QB and the second gate-off power line 8 in response to a set signal (a start signal or a carry output CRY(N−4)) of a preceding stage. The 5-1 thin film transistor T5c may discharge the voltage of the second control node QB to the second gate-off voltage line VSS through the activated 2-1 discharge path.

The 2-2 discharge unit may include a 5-2 thin film transistor T5q having a gate electrode connected to the first control node Q and providing a 2-2 discharge path between the second control node QB and the second gate-off voltage line 8. The 5-2 thin film transistor T5q may activate the 2-2 discharge path between the second control node QB and the second gate-off power line 8 in response to the control of the first control node Q. The 5-2 thin film transistor T5q may discharge the voltage of the second control node QB to the second gate-off voltage line VSS through the activated 2-2 discharge path.

The first output unit may share a gate output line 14 and include a first pull-up thin film transistor T6 activated by the control of a first control node Q and a first pull-down thin film transistor T7 activated by the control of a second control node QB. The first pull-up thin film transistor T6 may be activated in response to the voltage of the first control node Q and may output a clock signal GCLK(N) applied to a clock line 12 to the gate output line 14 as a gate output GOUT(N). The first pull-down thin film transistor T7 may be activated in response to the voltage of the second control node QB and may output a first gate-off voltage VGL applied to the first gate-off voltage line 6 to the gate output line 14 as a gate output GOUT(N).

The second output section may share a carry output line 16 and include a second pull-up thin film transistor T6c activated by the control of the first control node Q and a second pull-down thin film transistor T7c activated by the control of the second control node QB. The second pull-up thin film transistor T6c may be activated in response to the voltage of the first control node Q and may output a clock signal GCLK(N) applied to the clock line 12 to the carry output line 16 as a carry output CRY(N). The second pull-down thin film transistor T7c may be activated in response to the voltage of the second control node QB and may output a second gate-off voltage VSS applied to the second gate-off voltage line 8 to the carry output line 16 as a carry output CRY(N).

Each stage of the gate driving circuit according to one embodiment may further include an offset transistor T3q connected to the intermediate nodes of the 1-1 and 1-2 thin film transistors T1a, T1b and the intermediate nodes of the 3-1 and 3-2 thin film transistors T3_a and T3_b.

The offset transistor T3q may be activated in response to the first control node Q, and the activated offset transistor T3q can apply a high-potential power supply voltage VDD applied to the high-potential voltage line 4 as an offset voltage to the intermediate nodes of the 1-1 and 1-2 thin film transistors T1a, T1b and the intermediate nodes of the 3-1 and 3-2 thin film transistors T3_a and T3_b. Each of the 1-1 thin film transistor T1a and the 3-1 thin film transistor T3_a can minimize leakage current by having a negative voltage whose gate source voltage is lower than the threshold voltage due to the offset voltage VDD.

Each stage of the gate drive circuit according to one embodiment may further include a reset transistor T3no that resets the gate output line 14 in response to control of the reset node 18.

The reset transistor T3no can reset the gate output line 14 to the first gate off voltage line VGL in response to a reset signal or carry output CRY(N+4) of the subsequent stage applied to the reset node 18.

In a gate driving circuit according to one embodiment, the 4-1 and 4-2 thin film transistors T4a, T4b of the second charging section for charging the second control node QB may use a dual gate thin film transistor having a heterogeneous resistance structure according to one embodiment described above.

The 4-1 and 4-2 thin film transistors T4a and T4b according to one embodiment may use any one of the dual gate thin film transistors Ta-Tb according to various embodiments illustrated in FIGS. 2 to 13. Accordingly, since the 4-2 thin film transistor T4b has a heterogeneous structure in which the resistance is greater than the resistance of the 4-1 thin film transistor T4a, the voltage distributed to the 4-2 thin film transistor T4b may increase and the voltage distributed to the 4-1 thin film transistor T4a may decrease.

The 4-1 and 4-2 thin film transistors T4a and T4b according to one embodiment may use any one of the dual gate thin film transistors Ta_1-Tb and Ta_2-Tb according to various embodiments illustrated in FIG. 17 to FIG. 24. Accordingly, since the 4-1 thin film transistor T4a has a heterogeneous structure in which the resistance is smaller than that of the 4-2 thin film transistor T4b, the voltage distributed to the 4-1 thin film transistor T4a may decrease and the voltage distributed to the 4-2 thin film transistor T4b may increase.

Accordingly, the stress and deterioration of the 4-1 thin film transistor T4a operating in saturation mode may be reduced, and the overall stress and deterioration of the dual gate 4th thin film transistor T4a, T4b may be reduced. Accordingly, the reliability of the gate driving circuit may be improved by preventing multi-output of the gate output GOUT(N) and carry output CRY(N) of the gate driving circuit.

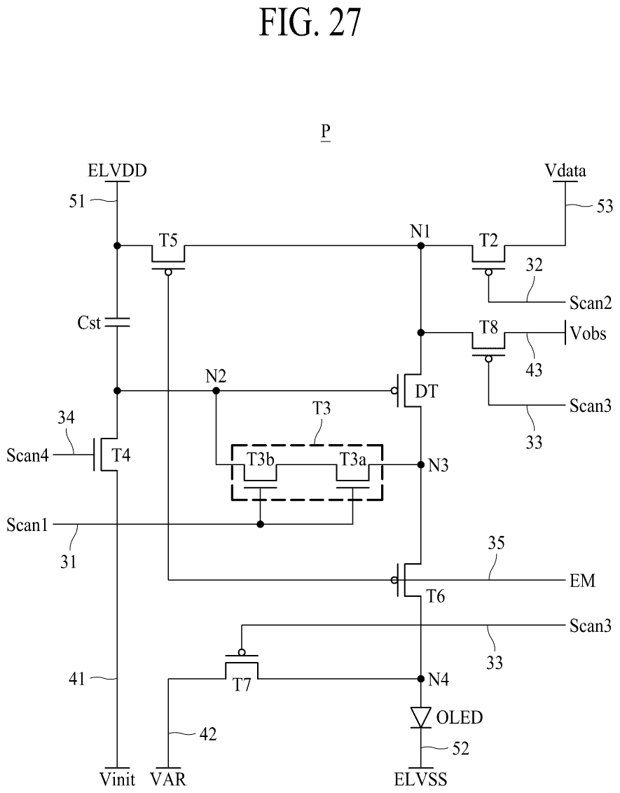

FIG. 27 is an equivalent circuit diagram illustrating a pixel circuit configuration according to one embodiment of the present disclosure.

Referring to FIG. 27, a subpixel P according to one embodiment may include a light emitting element (OLED) and a pixel circuit that independently drives the light emitting element (OLED), and the pixel circuit may include a driving thin film transistor DT and a plurality of thin film transistors T2 to T8 and a storage capacitor Cst.

Each of the thin film transistors DT, T2 to T8 of the pixel circuit can use any one of a polysilicon semiconductor, an amorphous silicon semiconductor, and an oxide semiconductor. In one embodiment, the thin film transistors DT and T2 to T7 of the pixel circuit may be configured as a P-type polysilicon transistor. In one embodiment, the thin film transistors DT and T2 to T8 of the pixel circuit may be configured as an N-type oxide transistor. In one embodiment, the thin film transistors DT and T2 to T8 of the pixel circuit may be configured by mixing a P-type polysilicon transistor and an N-type oxide transistor.

In one embodiment, the driving thin film transistor DT and some of the thin film transistors T2 and T4-T8 may be composed of fast-mobility P-type low-temperature polycrystalline silicon LTPS transistors, and the third thin film transistor may be composed of an N-type oxide transistor having a smaller off-state current (leakage current) than the LTPS transistor.

The third thin film transistor (T3, sampling transistor) may be connected to a second node N2 controlled by the first gate line 31 and connected to the gate electrode of the driving transistor DT, and a third node N3 connected to the drain electrode (second electrode) of the driving transistor DT. The third transistor T3 is turned on by the gate-on voltage of the first scan signal Scan1 supplied through the first gate line 31, and can connect the gate electrode and drain electrode of the driving transistor DT during the sampling period, thereby connecting the driving transistor DT in a diode structure.

The third transistor T3 according to one embodiment may include 3-1 and 3-2 thin film transistors T3a and T3b that are connected in series between a third node N3 and a second node N2 and share a gate electrode. The 3-1 and 3-2 thin film transistors T3a and T3b may use a dual gate thin film transistor having a heterogeneous resistance structure according to one embodiment described above.

The 3-1 and 3-2 thin film transistors T3a and T3b according to one embodiment may use any one of the dual gate thin film transistors Ta-Tb according to various embodiments illustrated in FIG. 2 to FIG. 13. Accordingly, since the 3-1 thin film transistor T3b has a heterogeneous structure in which the resistance is greater than the resistance of the 3-1 thin film transistor T3a, the voltage distributed to the 3-2 thin film transistor T3b may increase and the voltage distributed to the 3-1 thin film transistor T3a may decrease.

The 3-1 and 3-2 thin film transistors T3a, T3b according to one embodiment may use any one of the dual gate thin film transistors Ta_1-Tb and Ta_2-Tb according to various embodiments illustrated in FIG. 17 to FIG. 24. Accordingly, since the 3-1 thin film transistor T3a has a heterogeneous structure in which the resistance is smaller than that of the 3-2 thin film transistor T3b, the voltage distributed to the 3-1 thin film transistor T3a may decrease and the voltage distributed to the 3-2 thin film transistor T3b may increase.

Accordingly, the stress and deterioration of the 3-1 thin film transistor T3a may be reduced, and the overall stress and deterioration of the dual gate third thin film transistor T3 may be reduced. Therefore, even if the time for the third thin film transistor T3 to sample and compensate for the threshold voltage Vth of the driving thin film transistor DT increases, the deterioration of the third thin film transistor T3 may be reduced, thereby improving the reliability of the pixel circuit.

The second thin film transistor (T2, switching transistor) is controlled by a second gate line 32 and can connect a data line 53 and a first node N1 connected to a source electrode (first electrode) of a driving transistor DT. The second thin film transistor T2 is turned on by a gate-on voltage of a second scan signal Scan2 supplied through the second gate line 32, and can apply a data voltage Vdata supplied through the data line 53 to the driving transistor DT during a data programming period.

The fifth thin film transistor (T5, operation control transistor) is controlled by the fifth gate line 35 and can connect the first power line 51 supplying the high-potential power voltage ELVDD and the first node N1 of the driving transistor DT. The fifth thin film transistor T5 is turned on by the gate-on voltage of the light emission control signal EM supplied through the fifth gate line 35, and can apply the high-potential power voltage ELVDD supplied through the first power line 51 to the first node N1 of the driving transistor DT during the light emission period.

The sixth thin film transistor (T6, light emitting control transistor) is controlled by the fifth gate line 35 and can connect the third node N3 of the driving transistor DT and the fourth node N4 connected to the anode electrode of the light emitting element (OLED). The sixth thin film transistor T6 is turned on by the gate-on voltage of the light emitting control signal EM supplied through the fifth gate line 35, and can connect the third node N3 of the driving transistor DT and the anode electrode of the light emitting element (OLED) during the light emitting period.

The fourth thin film transistor (T4, first initialization transistor) is controlled by the fourth gate line 34 and can connect the second node N2 of the driving transistor DT and the first initialization voltage line 41. The fourth thin film transistor T4 is turned on by the gate-on voltage of the fourth scan signal Scan4 supplied through the fourth gate line 34, and can apply the first initialization voltage Vinit of the first initialization voltage line 41 to the second node N2 of the driving transistor DT during the initialization period.

The seventh thin film transistor (T7, second initialization transistor) is controlled by the third gate line 33 and can connect the second initialization voltage line 42 and the fourth node N4 connected to the anode of the light emitting element (OLED). The seventh thin film transistor T7 is turned on by the gate-on voltage of the third scan signal Scan3 supplied through the third gate line 33, and can apply the second initialization voltage VAR of the second initialization voltage line 42 to the fourth node N4 connected to the anode electrode of the light emitting element (OLED) during the initialization period. The second initialization voltage VAR may be expressed as an anode reset voltage.

The eighth thin film transistor (T8, third initialization transistor) is controlled by the third gate line 33 and can connect the third initialization voltage line 43 and the first node N1 of the driving transistor DT. The eighth thin film transistor T8 is turned on by the gate-on voltage of the third scan signal Scan3 supplied through the third gate line 33, and can supply the third initialization voltage Vobs of the third initialization voltage line 43 to the first node N1 of the driving transistor DT during the initialization period. The third initialization voltage Vobs may be expressed as an on bias stress voltage that suppresses the threshold voltage shift of the driving transistor DT.

The storage capacitor Cst may be connected between a first power line 51 and a second node N2 of a driving transistor DT. The storage capacitor Cst can charge a difference voltage between a high-potential power voltage ELVDD applied through the first power line 51 and a data voltage Vdata applied to the driving transistor DT and the second node N2. During a sampling period in which the driving transistor DT is connected in a diode structure through a sampling third thin film transistor T3, the storage capacitor Cst can sample and store a threshold voltage Vth of the driving transistor DT, and provide a data voltage with a threshold voltage compensated for to the second node N2 of the driving transistor DT. The storage capacitor Cst can hold the difference voltage between the high-potential power supply voltage ELVDD and the data voltage (Vdata+Vth) for which the threshold voltage of the driving transistor DT is compensated, by charging it to the target voltage, and can provide the held target voltage as the driving voltage of the driving transistor DT.

The driving transistor DT (first thin film transistor) may have a gate electrode connected to a second node N2, a source electrode (first electrode) connected to a first node N1, and a drain electrode (second electrode) connected to a third node N3. The driving transistor DT may control the amount of current flowing to the light emitting element (OLED) through the sixth thin film transistor T6 according to a target voltage charged in the storage capacitor Cst, thereby controlling the light emitting intensity of the light emitting element (OLED).

The light emitting element (OLED) may include an anode connected to a third node N3 of a driving transistor DT through a sixth thin film transistor T6, a cathode connected to a second power line 52 to which a low-potential power voltage ELVSS is applied, and an organic light emitting layer between the anode and the cathode. The light emitting element (OLED) may generate light with a luminance proportional to the amount of driving current supplied from the driving transistor DT through the sixth thin film transistor T6.

Referring to FIG. 25 and FIG. 27, the gate lines 31, 32, 33, and 34 may be driven by a plurality of scan driving circuits 210, 220 among the gate driving circuits 200, and the gate line 35 may be driven by the light emission control driving circuit 230 among the gate driving circuits 200.

As described above, the dual gate thin film transistor according to one embodiment of the present disclosure can reduce the voltage distribution difference between the first thin film transistor and second thin film transistor by having a heterogeneous structure in which the first thin film transistor and second thin film transistor have different resistances.

The dual gate thin film transistor according to one embodiment of the present disclosure has a heterogeneous resistance structure in which the resistance of the second thin film transistor is greater than the resistance of the first thin film transistor, thereby increasing the voltage distributed to the second thin film transistor and reducing the voltage distributed to the first thin film transistor.

The dual gate thin film transistor according to one embodiment of the present disclosure has a heterogeneous resistance structure in which the resistance of the first thin film transistor is smaller than the resistance of the second thin film transistor, thereby reducing the voltage distributed to the first thin film transistor and increasing the voltage distributed to the second thin film transistor.

Accordingly, the dual gate thin film transistor according to one embodiment of the present disclosure can reduce the difference in voltage distribution between the first thin film transistor and second thin film transistor, thereby reducing stress and deterioration of the first thin film transistor operating in saturation mode, and as a result, can reduce the overall stress and deterioration of the dual gate thin film transistor, thereby improving the reliability of the dual gate thin film transistor.

The gate driving circuit including a dual gate thin film transistor according to one embodiment of the present disclosure may improve the reliability of the gate driving circuit by reducing deterioration of the dual gate thin film transistor and may achieve a low power consumption effect.

A display device including a dual gate thin film transistor according to one embodiment of the present disclosure may improve the reliability of a pixel circuit by reducing deterioration of a dual gate thin film transistor in a pixel circuit, and may achieve a low power consumption effect.

The display device according to the present disclosure may be applied to all electronic devices. For example, the display device according to the present disclosure may be applied to mobile device, video phone, smart watch, watch phone, wearable device, foldable device, rollable device, bendable device, flexible device, curved device, electronic notebook, electronic book, portable multimedia player (PMP), personal digital assistant (PDA), MP3 player, mobile medical device, desktop PC, laptop PC, netbook computer, workstation, navigation system, vehicle navigation system, vehicle display device, television, wallpaper display device, signage device, game device, laptop, monitor, camera, camcorder, and home appliance.

The features, structures, effects, etc. described in the various examples of this specification described above are included in at least one example of this specification, and are not necessarily limited to just one example. Furthermore, the features, structures, effects, etc. illustrated in at least one example of this specification may be combined or modified in other examples by a person with ordinary skill in the art to which the technical idea of this specification belongs. Therefore, the contents related to such combinations and modifications should be interpreted as being included within the technical scope or rights of this specification.

The present disclosure described above is not limited to the aforementioned embodiments and the attached drawings, and it will be apparent to those skilled in the art to which this specification pertains that various substitutions, modifications, and changes are possible within the scope of the technical spirit of this disclosure. Therefore, the scope of this disclosure is indicated by the claims set forth below, and all changes or modified forms derived from the meaning and scope of the claims and their equivalent concepts should be interpreted as being included within the scope of this specification.

What is claimed is:

1. A dual gate thin film transistor comprising:
a first thin film transistor including a first gate electrode, a first drain electrode, a first source electrode, and a first channel part between the first drain electrode and the first source electrode; and
a second thin film transistor including a second gate electrode connected to the first gate electrode, a second drain electrode connected to the first source electrode, a second source electrode, and a second channel part between the second drain electrode and the second source electrode,
wherein the first channel part and the first gate electrode overlap with each other with a first insulating layer interposed between the first channel part and the first gate electrode, and
wherein the second channel part and the second gate electrode overlap with each other with a plurality of insulating layers including the first insulating layer and a second insulating layer interposed between the second channel part and the second gate electrode.

2. The dual gate thin film transistor of claim 1, wherein:
the first thin film transistor and second thin film transistor include an active layer in which the first channel part and second channel part are formed,
the first drain electrode is formed as a first conductorized part of the active layer in contact with the first channel part,
the first source electrode and the second drain electrode are integrally formed by a second conductorized part of the active layer in contact with the first channel part and second channel part between the first channel part and second channel part, and
the second source electrode is formed as a third conductorized part of the active layer in contact with the second channel part.

3. The dual gate thin film transistor of claim 2, further comprising:
a drain connection electrode connected to the first drain electrode through a first contact hole penetrating the plurality of insulating layers; and
a source connection electrode connected to the second source electrode through a second contact hole penetrating the plurality of insulating layers.

4. The dual gate thin film transistor of claim 3, wherein:
the first gate electrode is disposed on the first insulating layer,
the second gate electrode, the drain connection electrode, and the source connection electrode are disposed on the second insulating layer, and
the first gate electrode and the second gate electrode are connected to each other through a third contact hole penetrating the second insulating layer.

5. The dual gate thin film transistor of claim 4, further comprising:
a connection electrode connected to the second conductorized part through a fourth contact hole penetrating the plurality of insulating layers.

6. The dual gate thin film transistor of claim 3, further comprising:
a first light shielding electrode overlapping the first channel part with a buffer layer interposed therebetween; and
a second light shielding electrode overlapping the second channel part with the buffer layer interposed therebetween.

7. The dual gate thin film transistor of claim 6,
wherein the first light shielding electrode and second light shielding electrode are connected to the source connection electrode.

8. The dual gate thin film transistor of claim 3,
wherein the plurality of insulating layers further include a third insulating layer disposed on the second insulating layer between the second channel part and the second gate electrode.

9. The dual gate thin film transistor of claim 8, wherein:
the first gate electrode is disposed on the first insulating layer,
the second gate electrode is disposed on the third insulating layer, and
the first gate electrode and the second gate electrode are connected to each other through a third contact hole penetrating the second and third insulating layers.

10. The dual gate thin film transistor of claim 9, wherein:
the drain connection electrode is disposed on the second insulating layer and connected to the first drain electrode through the first contact hole penetrating the first insulating layer and second insulating layer, and
the source connection electrode is disposed on the second insulating layer and connected to the second source electrode through the second contact hole penetrating the first insulating layer and second insulating layer, or
the source connection electrode is disposed on the third insulating layer and connected to the second source electrode through the second contact hole penetrating the first to third insulating layers

11. The dual gate thin film transistor of claim 5, wherein:
the connection electrode is disposed on the second insulating layer and connected to the second conductorized part through the fourth contact hole penetrating the first insulating layer and second insulating layer, or
the connection electrode is disposed on the third insulating layer connected to the second conductorized part through the fourth contact hole penetrating the first to third insulating layers.

12. The dual gate thin film transistor of claim 1,
wherein a second capacitance between the second gate electrode and the second channel part of the second thin film transistor is smaller than a first capacitance between the first gate electrode and the first channel part of the first thin film transistor.

13. The dual gate thin film transistor of claim 1,
wherein a second resistance of the second thin film transistor is greater than a first resistance of the first thin film transistor.

14. A dual gate thin film transistor comprising:
a first thin film transistor including a first gate electrode, a first drain electrode, a first source electrode, and a first channel part between the first drain electrode and the first source electrode; and
a second thin film transistor including a second gate electrode connected to the first gate electrode, a second drain electrode connected to the first source electrode, a second source electrode, and a second channel part between the second drain electrode and the second source electrode,
wherein the second thin film transistor further comprises a second light shielding electrode overlapping the second channel part, and
wherein the first gate electrode and second gate electrode are disposed in the same layer and formed integrally as one continuous structure.

15. The dual gate thin film transistor of claim 14, wherein:
the first thin film transistor and second thin film transistor include an active layer in which the first channel part and second channel part are formed,
the first drain electrode is formed as a first conductorized part of the active layer in contact with the first channel part,
the first source electrode and the second drain electrode are integrally formed by a second conductorized part of the active layer in contact with the first channel part and second channel part between the first channel part and second channel part, and
the second source electrode is formed as a third conductorized part of the active layer in contact with the second channel part.

16. The dual gate thin film transistor of claim 15, wherein:
the first thin film transistor further includes a first light shielding electrode overlapping the first channel part with a buffer layer interposed therebetween,
the first gate electrode and the second gate electrode are disposed on a gate insulating layer covering the active layer, and
the first gate electrode is connected to the first light shielding electrode through a third contact hole penetrating the gate insulating layer and the buffer layer.

17. A display device comprising:
a display panel; and
a gate driving circuit for driving gate lines of the display panel,
wherein the gate driving circuit comprises a stage circuit outputting a gate signal to each of the gate lines,
the stage circuit includes:
an output unit for outputting the gate signal through a gate output line in response to a first control node and control of the first control node;
a first charging unit for charging the first control node;
a first discharging unit for discharging the first control node;
a second charging unit for charging a second control node; and
a second discharging unit for discharging the second control node,
wherein the second charging unit includes a dual gate thin film transistor according to claim 1, connected between a high potential power supply line supplied with a high potential power voltage and the second control node, and
wherein the first gate electrode, second gate electrode, and the first drain electrode of the dual gate thin film transistor are connected to the high potential power supply line, and the second source electrode is connected to the second control node.

18. A display device comprising:
a plurality of subpixels disposed in a display area of a display panel,
wherein each of the plurality of subpixels includes a light emitting element and a pixel circuit for independently driving the light emitting element,
the pixel circuit comprising:
a driving transistor for driving the light emitting element; and
a sampling thin film transistor connecting a gate electrode and a drain electrode of the driving transistor,
wherein the sampling thin film transistor includes a dual gate thin film transistor according to claim 1.

19. The display device of claim 18, wherein:
the first drain electrode of the dual gate thin film transistor is connected to the drain electrode of the driving transistor,
the first gate electrode and second gate electrode are connected to a gate line controlling the sampling thin film transistor, and
the second source electrode is connected to the gate electrode of the driving transistor.

20. A dual gate thin film transistor comprising:
a first thin film transistor including a first gate electrode, a first drain electrode, a first source electrode, and a first channel part between the first drain electrode and the first source electrode; and
a second thin film transistor including a second gate electrode connected to the first gate electrode, a second drain electrode connected to the first source electrode, a second source electrode, and a second channel part between the second drain electrode and the second source electrode,
wherein the first channel part and the second channel part are formed on a same layer, and
wherein a first distance between the first channel part and the first gate electrode is less than a second distance between the second channel part and the second gate electrode.
